(19) United States
(12) Patent Application Publication
(10) Pub. No.: US 2025/0120045 A1
(43) Pub. Date: Apr. 10, 2025

(54) CONTAINER AND DATA CENTER OF CONTAINER

(71) Applicant: BITMAIN TECHNOLOGIES INC., Beijing (CN)

(72) Inventors: Fengjie Li, Beijing (CN); Hangkong Hu, Beijing (CN); Shaoming Huang, Beijing (CN); Yongbo Ge, Beijing (CN); Xiaoxiong Zhang, Beijing (CN); Tuo Geng, Beijing (CN); Tianhao Li, Beijing (CN); Hongshan Zhu, Beijing (CN); Wenkai Cui, Beijing (CN); Minghao Li, Beijing (CN); Shuangquan Hua, Beijing (CN)

(21) Appl. No.: 18/911,175

(22) Filed: Oct. 9, 2024

(30) Foreign Application Priority Data
Oct. 10, 2023 (CN) 202322723638.5

(51) Int. Cl. H05K 7/20

(52) U.S. Cl. CPC H05K 7/20272; H05K 7/2079

(57) ABSTRACT

The present application provides a container and a data center of the container. A box is provided with an accommodating cavity for placing an electronic device, and a heat dissipation pipeline includes a housing with a cooling cavity, where the cooling cavity is filled with cooling liquid, and high-temperature gas in the accommodating cavity enters the cooling cavity through an inlet, and low-temperature gas in the cooling cavity generated after heat exchange with the cooling liquid enters the accommodating cavity through an outlet for cooling the electronic device to form heat dissipation circulation.

### CROSS-REFERENCE TO RELATED APPLICATIONS

The present application claims priority to Chinese Application No. 202322723638.5, filed on Oct. 10, 2023, which is hereby incorporated by reference in its entirety.

### TECHNICAL FIELD

The present application relates to the technical field of a data center and, in particular, to a container and a data center of the container.

### BACKGROUND

A data center of the container refers to taking the container as a carrier, and an electronic device such as a server component is loaded in the container to form a data center.

In the related art, the electronic device such as the server component will release heat during a working process. Generally, the data center of the container performs refrigeration through a refrigeration device connected to an outside of the container. The refrigeration device can absorb high-temperature air in the container and perform heat exchange to reduce the temperature, so as to realize heat dissipation of the electronic device such as the server components in the data center of the container.

However, the above-mentioned heat dissipation method has poor heat dissipation effect.

### SUMMARY

In order to solve at least one problem mentioned in the background technology, the present application provides a container and a data center of the container, aiming at solving the technical problems that the heat dissipation mode in the related art has poor heat dissipation effect.

In order to achieve the above purpose, in a first aspect, the present application provides a container, including a box and a heat dissipation apparatus, where the box is provided with an accommodating cavity for placing an electronic device; the heat dissipation apparatus is located in the accommodating cavity and installed on an inner wall surface of the box;
the heat dissipation apparatus comprises a housing with a cooling cavity, where the cooling cavity is filled with a cooling liquid; the housing is provided with an inlet and an outlet which communicate the cooling cavity and the accommodating cavity; high-temperature gas in the accommodating cavity enters the cooling cavity through the inlet; and low-temperature gas in the cooling cavity generated after heat exchange with the cooling liquid enters the accommodating cavity through the outlet.

In an implementation, the above container further comprises a fan configured to transport the high-temperature gas in the accommodating cavity into the cooling cavity; and
the fan is installed in the cooling cavity, and an air inlet of the fan faces the inlet; or the fan is installed in the accommodating cavity, and an air outlet of the fan faces the inlet.

In an implementation, in the above container, the heat dissipation apparatus further includes a protective mesh, which is connected to the housing and covers the inlet; or, the protective mesh covers the fan.

In an implementation, in the above container, the heat dissipation apparatus further includes a liquid inlet pipe, a liquid outlet pipe and a cooling member, wherein the cooling member is located in the cooling cavity and between the inlet and the outlet; an axial direction of the inlet intersects with an axial direction of the outlet; a cavity of the cooling member is filled with the cooling liquid, and both the liquid inlet pipe and the liquid outlet pipe are communicated with the cavity of the cooling member, wherein the liquid inlet pipe is configured to introduce the cooling liquid into the cavity of the cooling member, and the liquid outlet pipe is configured to discharge a waste liquid in the cavity of the cooling member generated by the cooling liquid after a cooling process.

In an implementation, in the above container, the number of the inlet is plural, and the plurality of inlets are arranged at intervals along a first direction; and
the number of the outlet is plural, and along a second direction, a part of the outlets are located at one side of the inlets, and another part of the outlets are located at the other side of the inlets, and the second direction intersects with the first direction.

In an implementation, in the above container, the number of the cooling member is two, and the two cooling members are respectively arranged close to the outlets on both sides of the inlets.

In an implementation, in the above container, the number of the heat dissipation apparatus is plural, and the plurality of heat dissipation apparatuses are arranged on a top wall surface or a side wall surface of the box at intervals; or, a part of the heat dissipation apparatuses are installed on the top wall surface of the box at intervals, and another part of the heat dissipation apparatuses are installed on the side wall surface of the box at intervals, wherein the top wall surface and the side wall surface are adjacent.

In an implementation, in the above container, the container further includes a first communicating pipe and a second communicating pipe, and
the first communicating pipe is communicated with a liquid inlet pipe of the plurality of heat dissipation apparatuses for transporting the cooling liquid; or, the second communicating pipe is communicated with a liquid outlet pipe of the plurality of heat dissipation apparatuses for transporting a waste liquid.

In a second aspect, the present application further provides a data center of a container, including an electronic device and the container as described in the first aspect, where the electronic device is located in the box of the container.

In an implementation, in the above data center of the container, along a height direction of the container, an orthographic projection of the electronic device on a bottom wall of the container is arranged at intervals from an orthographic projection of the heat dissipation apparatus of the container on the bottom wall of the container;
and/or, along a height direction perpendicular to the box, an orthographic projection of the electronic device on a side wall of the container is arranged at intervals from an orthographic projection of the heat dissipation apparatus of the container on the side wall of the container.

In the container and data center of the container provided by the present application, the box is provided with an accommodating cavity for placing the electronic device, and a heat dissipation pipeline includes a housing with a cooling cavity, where the cooling cavity is filled with cooling liquid, and the housing is provided with an inlet and an outlet for communicating the cooling cavity with the accommodating cavity. High-temperature gas in the accommodating cavity enters the cooling cavity through the inlet, and low-temperature gas in the cooling cavity generated after heat exchange with the cooling liquid enters the accommodating cavity through the outlet. In this way, the heat dissipation apparatus can exchange heat with the high-temperature gas, obtain the heat of the high-temperature gas, convert the high-temperature gas into low-temperature gas, which finally enter the accommodating cavity of the container through the outlet for cooling the electronic device such as a server component, so as to form heat dissipation circulation. The heat dissipation apparatus is located in the accommodating cavity and installed on an inner wall surface of the box, a distance between the heat dissipation apparatus and the electronic device is short, and a time for the high-temperature gas to enter the heat dissipation apparatus is short, which can shorten the flow time of the gas and further improve the cooling efficiency of the heat dissipation apparatus. In addition, the time for the low-temperature gas to enter the accommodating cavity is short, and the low-temperature gas can maintain a good heat dissipation effect, which is not easy to generate heat exchange. The heat exchange effect between the low-temperature gas and the electronic device is good, which can improve the heat dissipation effect of the heat dissipation apparatus, thus meeting the user's demand for a high heat dissipation effect of the heat dissipation apparatus.

The structure of the present application provided by the present application, as well as its other application purposes and beneficial effects, will be more obvious and understandable by describing the preferred embodiment in conjunction with the accompanying drawings.

### BRIEF DESCRIPTION OF DRAWINGS

In order to explain the technical scheme in embodiments of the present application or the prior art more clearly, the drawings needed to be used in the description of the embodiments or the prior art will be briefly introduced below. Obviously, the drawings in the following description are some embodiments of the present application, and for those skilled in the art, other drawings can be obtained according to these drawings without creative effort.

FIG. 1 is a schematic diagram of a three-dimensional structure of a container provided by an embodiment of the present application.

FIG. 2 is a schematic diagram of a three-dimensional structure of a heat dissipation apparatus of a container provided by an embodiment of the present application from a perspective.

FIG. 3 is an enlarged structural schematic diagram at position A in FIG. 2.

FIG. 4 is an enlarged structural schematic diagram at position B in FIG. 2.

FIG. 5 is a schematic diagram of a three-dimensional structure of a heat dissipation apparatus of a container provided by an embodiment of the present application from another perspective.

FIG. 6 is a structural schematic diagram of a container provided by an embodiment of the present application from a top view.

### DESCRIPTION OF REFERENCE NUMERALS

10—container; X-first direction; Y-the second direction; 100—box; 101—accommodating cavity;
200—heat dissipation apparatus; 210—housing; 211—cooling cavity; 212—inlet; 213—outlet;
300—fan; 400—protective mesh; 220—liquid inlet pipe; 230—liquid outlet pipe;
240—cooling member; 241—cooling pipe; 242—fin; 250—first communicating pipe; 260—second communicating pipe; 500—mounting plate.

Through the above drawings, clear embodiments of the present application has been shown, which will be described in more detail later. These drawings and written descriptions are not intended to limit the scope of the concept of the present application in any way, but to explain the concept of the present application to those skilled in the art by referring to specific embodiments.

### DESCRIPTION OF EMBODIMENTS

In the related art, a container has a space for placing an electronic device such as a server component, and heat exchange is realized through a heat dissipation apparatus placed outside a top of the container, so as to achieve heat dissipation effect. However, a distance between the heat dissipation apparatus located outside the container and the electronic device is large, a flow path of the gas is long, and a flow time of the gas is long, thus the heat dissipation efficiency of the heat dissipation apparatus is poor, which will further affect the heat dissipation effect of the heat dissipation apparatus and cannot meet the user's demand for high heat dissipation effect of the heat dissipation apparatus.

Based on the above technical problems, the embodiments of the present application provide a container and a data center of the container. The box is provided with an accommodating cavity for placing the electronic device, and a heat dissipation pipeline includes a housing with a cooling cavity, where the cooling cavity is filled with cooling liquid, and the housing is provided with an inlet and an outlet for communicating the cooling cavity with the accommodating cavity. High-temperature gas in the accommodating cavity enters the cooling cavity through the inlet, and low-temperature gas in the cooling cavity generated after heat exchange with the cooling liquid enters the accommodating cavity through the outlet. In this way, the heat dissipation apparatus can exchange heat with the high-temperature gas, obtain the heat of the high-temperature gas, convert the high-temperature gas into low-temperature gas, which finally enter the accommodating cavity of the container through the outlet for cooling the electronic device such as a server component, so as to form heat dissipation circulation. The heat dissipation apparatus is located in the accommodating cavity and installed on an inner wall surface of the box, a distance between the heat dissipation apparatus and the electronic device is short, and a time for the high-temperature gas to enter the heat dissipation apparatus is short, which can shorten the flow time of the gas and further improve the cooling efficiency of the heat dissipation apparatus. In addition, the time for the low-temperature gas to enter the accommodating cavity is short, and the low-temperature gas can maintain a good heat dissipation effect, which is not easy to generate heat exchange. The heat exchange effect between the low-temperature gas and the electronic device is good, which can improve the heat dissipation effect of the heat dissipation apparatus, thus meeting the user's demand for a high heat dissipation effect of the heat dissipation apparatus.

In order to make the purpose, technical scheme and advantages of this application more clear, the technical scheme in the embodiments of this application will be described in more detail with the accompanying drawings in the preferred embodiments of the present application. In the drawings, the same or similar reference numerals indicate the same or similar structural members or structural members with the same or similar functions throughout. The described embodiments is part of structural embodiments of the present application, not all of the structural embodiments. The embodiments described below by referring to the accompanying drawings are exemplary and are intended to explain the preset application, but not to be construed as limitations of the present application. Based on the embodiments in this application, all other embodiments obtained by those skilled in the art without creative effort belong to the protection scope of this application. Hereinafter, embodiments of the present application will be described in detail with reference to the accompanying drawings.

On a first aspect, an embodiment of the present application provides a data center of a container, which comprises an electronic device and a container, where the electronic device is located in a box in the container.

It can be understood that the number of electronic devices can be arbitrary. For example, the number of electronic devices can be two, three, four, five, etc. The embodiments of the present application does not limit the specific number of the electronic devices, nor does it limit the above examples.

It should be noted that the electronic device can be a server, a personal computer, a mobile phone, or a single device with different functions, such as a battery with power supply function, such as a memory with storage function, etc. The embodiments of the present application does not limit the specific form of the electronic device, nor is it limited to the above examples.

As an alternative embodiment, along a height direction of the container, an orthographic projection of the electronic device on a bottom wall of the container is arranged at intervals from an orthographic projection of the heat dissipation apparatus of the container on the bottom wall of the container. In this way, the heat dissipation apparatus can be installed in an idle position of the box, which is convenient for a staff to adjust or maintain the heat dissipation apparatus. For example, the staff can adjust a heat dissipation rate of the heat dissipation apparatus, or adjust opening or closing of the heat dissipation apparatus.

Specifically, the heat dissipation apparatus can be installed on the bottom wall or a top wall of the container. In order to facilitate high-temperature gas to enter the heat dissipation apparatus, the heat dissipation apparatus can be installed on the top wall of the container.

As another alternative embodiment, along a height direction perpendicular to the box, an orthographic projection of the electronic device on a side wall of the container is arranged at intervals from an orthographic projection of the heat dissipation apparatus of the container on the side wall of the container. In this way, the heat dissipation apparatus can be installed in the idle position of the box, which is convenient for the staff to adjust or maintain the heat dissipation apparatus. For example, the staff can adjust the heat dissipation rate of the heat dissipation apparatus, or adjust the opening or closing of the heat dissipation apparatus.

The embodiments of the present application does not limit the specific position of the heat dissipation apparatus on the box, nor is it limited to the above examples.

In the following, the example that along the height direction of the container, the orthographic projection of the electronic device on the bottom wall of the container is arranged at intervals from the orthographic projection of the heat dissipation apparatus of the container on the bottom wall of the container, and the heat dissipation apparatus is installed on the top wall of the container is taken for illustration.

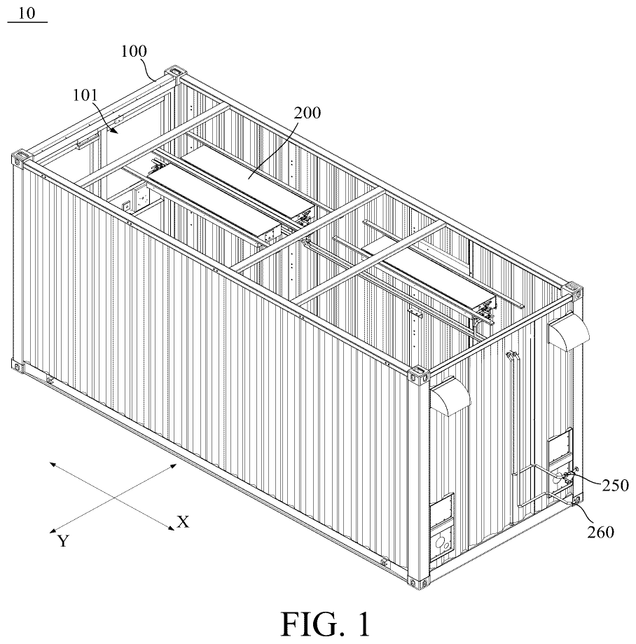

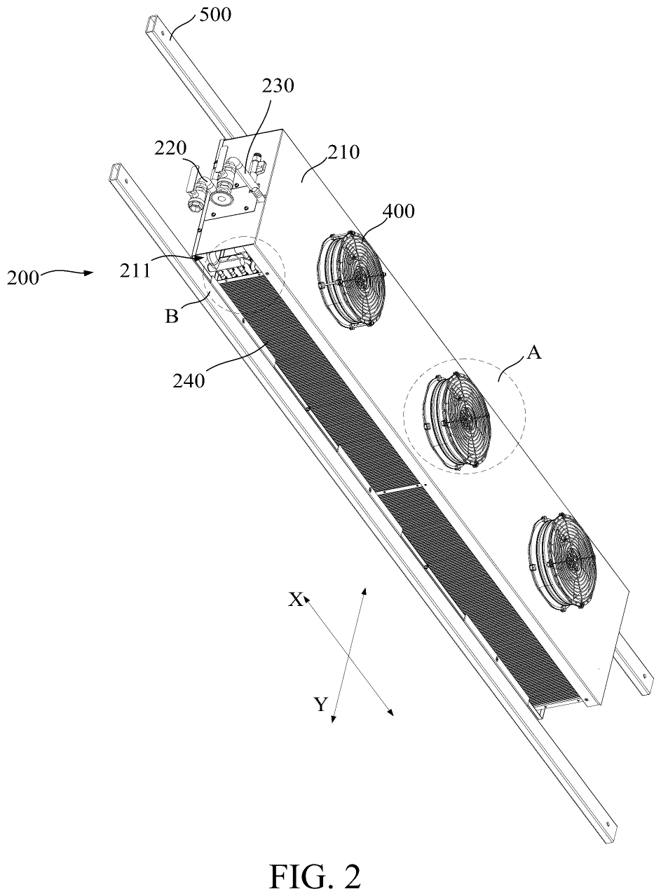

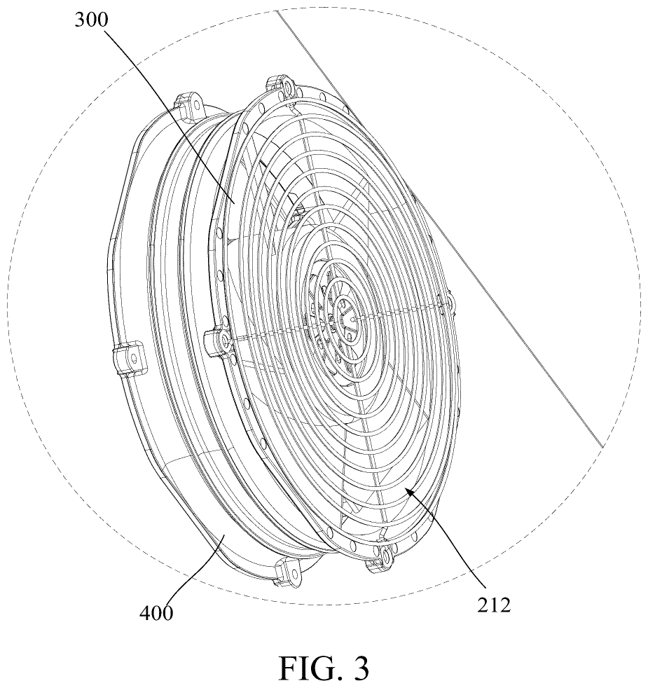

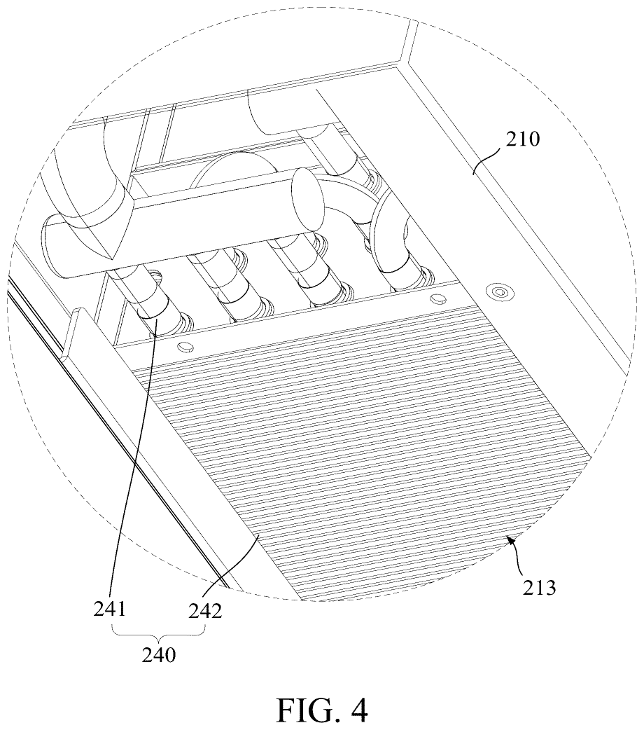

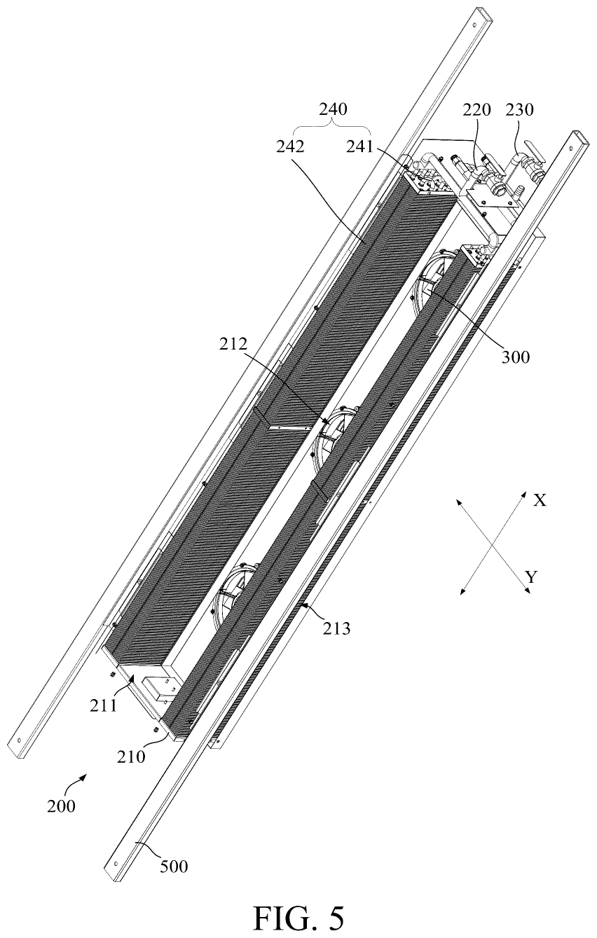

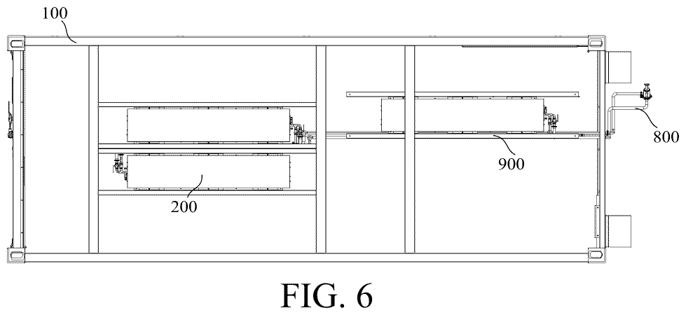

FIG. 1 is a schematic diagram of a three-dimensional structure of a container provided by an embodiment of the present application. FIG. 2 is a schematic diagram of a three-dimensional structure of a heat dissipation apparatus of a container provided by an embodiment of the present application from a perspective. FIG. 3 is an enlarged structural schematic diagram at position A in FIG. 2. FIG. 4 is an enlarged structural schematic diagram at position B in FIG. 2. FIG. 5 is a schematic diagram of a three-dimensional structure of a heat dissipation apparatus of a container provided by an embodiment of the present application from another perspective. FIG. 6 is a structural schematic diagram of a container provided by an embodiment of the present application from a top view.

In a second aspect, referring to FIG. 1, an embodiment of the present application also provides a container 10, which includes a box 100 and a heat dissipation apparatus 200, and the box 100 has an accommodating cavity 101 for placing the electronic device.

It should be noted that the shape of the box 100 can be arbitrary. For example, the shape of the box 100 can be a cube, a cylinder, a triangular cylinder, etc. The specific shape of the box 100 is not limited in the embodiments of the present application, nor is it limited to the above examples.

The following description takes the shape of the box 100 being a cuboid as an example.

Specifically, the heat dissipation apparatus 200 is located in the accommodating cavity 101 and installed on the inner wall surface of the box 100. A distance between the heat dissipation apparatus 200 and the electronic device is small, and a time for high-temperature gas to enter the heat dissipation apparatus 200 is short, which can shorten the flow time of the gas and further improve the cooling efficiency of the heat dissipation apparatus 200.

Referring to FIG. 2 to FIG. 5, the heat dissipation apparatus 200 includes a housing 210 with a cooling cavity 211, and the cooling cavity 211 is filled with a cooling liquid. The housing 210 is provided with an inlet 212 and an outlet 213 which communicating the cooling cavity 211 with the accommodating cavity 101. High-temperature gas in the accommodating cavity 101 enters the cooling cavity 211 through the inlet 212, and low-temperature gas in the cooling cavity 211 generated after heat exchange with the cooling liquid enters the accommodating cavity 101 through the outlet 213. That is, the high-temperature gas in the accommodating cavity 101 can enter the cooling cavity 211 through the inlet 212, and be transformed into the low-temperature gas after heat being dissipated by the heat dissipation apparatus 200, and the low-temperature gas enters the accommodating cavity 101 through the outlet 213, so as to realize the heat dissipation of the electronic device.

Specifically, the high-temperature gas entering the cooling cavity 211 through the inlet 212 comes into contact with the cooling liquid in the heat dissipation apparatus 200, so that the temperature of the cooling liquid becomes higher, and the cooling liquid is transformed into a waste liquid. After the high-temperature gas exchanges heat with the cooling liquid, the high-temperature gas is converted into the low-temperature gas, which can exchange heat with the electronic device located in the accommodating cavity 101 to realize heat dissipation of the electronic device and form a heat dissipation cycle.

Through the above arrangement, the heat dissipation apparatus 200 can exchange heat with the high-temperature gas, obtain the heat of the high-temperature gas, convert the high-temperature gas into the low-temperature gas, where the low-temperature gas finally enter the accommodating cavity 101 of the container 10 through the outlet 213 for cooling the electronic device such as a server component, so as to achieve heat dissipation circulation. A distance between the heat dissipation apparatus 200 and the electronic device is short, and a time for the high-temperature gas to enter the heat dissipation apparatus 200 is short, which can shorten the flow time of the gas and further improve the cooling efficiency of the heat dissipation apparatus 200. The time for the low-temperature gas to enter the accommodating cavity 101 is short, and the low-temperature gas can maintain a good heat dissipation effect, which is not easy to generate heat exchange. The heat exchange effect between the low-temperature gas and the electronic device is good, which can improve the heat dissipation effect of the heat dissipation apparatus 200, thus meeting the user's demand for a high heat dissipation effect of the heat dissipation apparatus 200.

As an alternative embodiment, referring to FIG. 2, FIG. 3 and FIG. 5, the container 10 further includes a fan 300 configured to transport the high-temperature gas in the accommodating cavity 101 into the cooling cavity 211 through the inlet 212. It can be understood that the fan 300 can be an axial flow fan, and the air inlet and the air outlet are located on both sides of the axial surface respectively.

In some specific embodiments, the fan 300 is installed in the cooling cavity 211, and the air inlet of the fan 300 faces the inlet 212. At this time, the fan 300 can transport the high-temperature gas in the accommodating cavity 101 into the cooling cavity 211 through the inlet 212. In this way, the time required for the high-temperature gas to enter the heat dissipation apparatus 200 through the inlet 212 is shorter, and the time required for the heat dissipation apparatus 200 to cool the high-temperature gas is shorter, so that the heat dissipation efficiency of the heat dissipation apparatus 200 can be improved, and the heat exchange efficiency of the electronic device can be further improved, thus being beneficial to meeting the user's demand for higher heat dissipation effect of the heat dissipation apparatus 200.

In other specific embodiments, referring to FIG. 2, FIG. 3 and FIG. 5, the fan 300 is installed in the accommodating cavity 101, and the air outlet of the fan 300 faces the inlet 212. At this time, the fan 300 can transport the high-temperature gas in the accommodating cavity 101 to the cooling cavity 211 through the inlet 212. In this way, the time required for the high-temperature gas to enter the heat dissipation apparatus 200 through the inlet 212 is shorter, and the time required for the heat dissipation apparatus 200 to cool the high-temperature gas is shorter, so that the heat dissipation efficiency of the heat dissipation apparatus 200 can be improved, and the heat exchange efficiency of the electronic device can be further improved, thus being beneficial to meeting the user's demand for higher heat dissipation effect of the heat dissipation apparatus 200.

It can be understood that in order to increase the volume of the cooling cavity 211, in an embodiment of the present application, the fan 300 is installed in the accommodating cavity 101, and the air outlet of the fan 300 faces the inlet 212.

As an alternative embodiment, referring to FIG. 2 and FIG. 3, the heat dissipation apparatus 200 further includes a protective mesh 400. The protective mesh 400 may be connected with the housing 210.

In some specific embodiments, the protective mesh 400 is connected to the housing 210 and covers the inlet 212. If the protective mesh 400 is not provided, impurities in the accommodating cavity 101 will easily enter the cooling cavity 211 through the inlet 212, which will affect gas circulation volume of the cooling cavity 211, reduce contact area between the high-temperature gas and the cooling liquid, and further reduce the heat dissipation efficiency of the heat dissipation apparatus 200. In addition, if the protective mesh 400 is not provided, impurities in the accommodating cavity 101 may be trapped between the blades of the fan 300, which will affect the normal operation of the fan 300 and further affect the heat dissipation apparatus 200 to obtain the high-temperature gas in the accommodating cavity 101.

In other specific embodiments, referring to FIG. 2 and FIG. 3, the protection mesh 400 covers the fan 300. If the protective mesh 400 is not provided, impurities in the accommodating cavity 101 will easily enter the cooling cavity 211 through the inlet 212, which will affect gas circulation volume of the cooling cavity 211, reduce contact area between the high-temperature gas and the cooling liquid, and further reduce the heat dissipation efficiency of the heat dissipation apparatus 200. In addition, if the protective mesh 400 is not provided, impurities in the accommodating cavity 101 may be trapped between the blades of the fan 300, which will affect the normal operation of the fan 300 and further affect the heat dissipation apparatus 200 to obtain the high-temperature gas in the accommodating cavity 101.

It can be understood that the protective mesh 400 can also prevent the fan 300 in operation from causing damage to the staff, and can better protect the staff for maintenance or adjustment.

In this embodiment, the protection mesh 400 covers the fan 300.

As an alternative embodiment, referring to FIG. 2, FIG. 4 and FIG. 5, the heat dissipation apparatus 200 further includes a liquid inlet pipe 220, a liquid outlet pipe 230 and a cooling member 240, where the cooling member 240 is located in the cooling cavity 211 and between an orifice of the inlet 212 and an orifice of the outlet 213; an axial direction of the inlet 212 intersects with an axial direction of the outlet 213. A cavity of the cooling member 240 is filled with the cooling liquid, and both the liquid inlet pipe 220 and the liquid outlet pipe 230 are communicated with the cavity of the cooling member 240, where the liquid inlet pipe 220 is configured to introduce the cooling liquid into the cavity of the cooling member 240, and the liquid outlet pipe 230 is configured to discharge a waste liquid generated by the cooling liquid in the cavity of the cooling member 240 after a cooling process.

It can be understood that, as shown in FIG. 2, FIG. 4 and FIG. 5, the cooling member 240 may include cooling pipes 241 which are connected with each other and fins 242, where a cooling liquid circulates in the cooling pipe 241, and the cavity of the cooling member 240 is the tubular cavity of the cooling pipe 241. A fin 242 can be connected and sleeved with a plurality of cooling pipes 241, and the cooling pipes 241 can be curved pipes, straight pipes or combined pipes with curved pipes and straight pipes. The cooling pipe 241 can communicate with the liquid outlet pipe 230 and the liquid inlet pipe 220 at the same time, and the cooling pipe 241 obtains the cooling liquid provided by the liquid inlet pipe 220. After the cooling of the high-temperature gas is completed, the cooling liquid is converted into a waste liquid, and the cooling pipe 241 can transport the waste liquid to the liquid outlet pipe 230 to discharge the waste liquid. By providing the cooling member 240, the heat dissipation apparatus 200 can realize the process of transforming the high-temperature gas into the low-temperature gas.

In the embodiments of the present application, the cooling pipe 241 may be a combined pipe with a curved pipe and a straight pipe.

Further, the number of fins 242 may be plural, and the plurality of fins 242 may form a channel for the low-temperature gas to circulate. On the one hand, the fins 242 can fix the cooling member 240 in the housing 210, and on the other hand, the fins 242 can form a channel for low-temperature gas to circulate. One end of the channel communicates with the cooling cavity 211 for guiding the high-temperature gas introduced through the inlet 212 so that the high-temperature gas flows through the cooling member 240; and the other end of the channel is configured to output the low-temperature gas, that is, the other end of the channel is the above-mentioned outlet 213.

As an alternative embodiment, referring to FIG. 2 and FIG. 5, the number of inlets 212 is plural, and the plurality of inlets 212 are arranged at intervals along a first direction X.

Further, the number of outlets 213 is plural. Along the second direction Y, a part of the outlets 213 are located at one side of the inlet 212, and another part of the outlet 213 is located at the other side of the inlet 212. The second direction Y intersects with the first direction X.

It can be understood that an angle between the first direction X and the second direction Y can be arbitrary. For example, the angle can be 30°, 60°, 90°, 120°, 150°, etc. The embodiments of the present application does not limit the specific angle between the first direction X and the second direction Y, nor is it limited to the above examples.

In the following, the angle between the first direction X and the second direction Y being 90° is taken as an example. Referring to FIG. 1, FIG. 2 and FIG. 5, the first direction X is the length direction of the housing 210, and the second direction Y is the width direction of the housing 210.

It should be noted that both the number of inlets 212 and the number of outlets 213 can be arbitrary. For example, the number of the inlets 212 can be two, three, four, five, etc., and the number of outlets 213 can be two, three, four, five, etc. The embodiments of the present application does not limit the number of the inlets 212 and the number of the outlets 213, nor are they limited to the above examples.

The following description takes the number of the inlets 212 being three and the number of the outlets 213 being two as an example.

By arranging a plurality of inlets 212, the contact area between the accommodating cavity 101 and the orifices of the inlets 212 can be increased, so as to improve the speed of introducing the high-temperature gas into the cooling cavity 211 by the inlets 212 and improve the heat dissipation efficiency of the heat dissipation apparatus 200. By arranging a plurality of outlets 213, the contact area between the accommodating cavity 101 and the orifices of the outlets 213 can be increased, so as to improve the speed at which the outlets 213 lead out the low-temperature gas to the accommodating cavity 101, thereby improving the heat dissipation efficiency of the heat dissipation apparatus 200. By arranging the outlets 213 on the opposite sides of the inlet 212, low-temperature gas can be released from different positions, so that the temperature distribution in the heat dissipation apparatus 200 is balanced and the heat dissipation apparatus 200 is prevented from being damaged due to poor temperature uniformity.

As an alternative embodiment, as shown in FIG. 2 and FIG. 5, the number of the cooling members 240 is two, and the two cooling members 240 are respectively arranged near the outlets 213 located at both sides of the inlet, and the liquid outlet pipe 230 and the liquid inlet pipe 220 are both communicated with the two cooling members 240.

It can be understood that in order to increase the outlet speed of the outlet 213, a projection of the outlet 213 on the surface of the corresponding housing 210 may cover the projection of the surface of the corresponding housing 210. At this time, the plurality of fins 242 of the cooling member 240 may form a plurality of channels, and the plurality of channels may jointly form an outlet 213.

By arranging the cooling member 240 and two outlets 213 corresponding to the two cooling members 240, compared with one cooling member 240, the rate for the cooling members 240 to convert the high-temperature gas into the low-temperature gas can be improved, thereby improving the heat dissipation efficiency of the heat dissipation apparatus 200. In addition, by placing the two cooling members 240 respectively close to the outlets 213 on both sides of the inlet 212, the outlets 213 can release the low-temperature gas from different positions, thus balancing the temperature distribution in the heat dissipation apparatus 200, avoiding the damage of the heat dissipation apparatus 200 due to poor temperature uniformity. Further, the efficiency of releasing the low-temperature gas from the outlets 213 is high, which can improve the heat dissipation effect of the heat dissipation apparatus 200.

As an alternative embodiment, referring to FIG. 1 and FIG. 6, the number of the heat dissipation apparatuses 200 is plural.

It can be understood that the number of heat dissipation apparatuses 200 can be two, three, four, five, etc. The embodiments of the present application does not limit the specific number of the heat dissipation apparatuses 200, nor is it limited to the above examples.

The following description takes the number of the heat dissipation apparatuses 200 being three as an example.

It can be understood that the box 100 has a top wall surface and a side wall surface, which are adjacent to each other. The top wall surface is the top surface of the inner wall of the box 100, and the side wall surface is the side surface of the inner wall of the box 100.

In some specific embodiments, a plurality of heat dissipation apparatuses 200 are arranged on a top wall surface or a side wall surface of the box 100 at intervals. In other specific embodiments, a part of the heat dissipation apparatuses 200 are installed on the top wall surface of the box 100 at intervals, and another part of the heat dissipation apparatuses 200 are installed on the side wall surface of the box 100 at intervals. That is, the heat dissipation apparatus 200 can be installed at any position on the inner wall of the box 100 of the container 10. Through the above arrangement, compared with installing the heat dissipation apparatuses 200 outside the box 100, a distance between the heat dissipation apparatuses 200 and electronic device is shorter, and a time for the high-temperature gas to enter the heat dissipation apparatuses 200 is shorter, which can shorten the flow time of the gas and further improve the cooling efficiency of the heat dissipation apparatuses 200.

In the embodiment of the present application, referring to FIG. 1 and FIG. 6, a plurality of heat dissipation apparatuses 200 are arranged on the top wall surface of the box 100 at intervals.

As an alternative embodiment, referring to FIG. 1 and FIG. 6, the container 10 further includes a first communicating pipe 250 and a second communicating pipe 260, both of which can transport liquid.

In some specific embodiments, the first communicating pipe 250 communicates with a liquid inlet pipes 220 of the plurality of heat dissipation apparatuses 200 for transporting the cooling liquid. In other specific embodiments, the second communicating pipe 260 communicates with a liquid outlet pipes 230 of the plurality of heat dissipation apparatuses 200 for transporting a waste liquid.

It should be noted that both the first communicating pipe 250 and the second communicating pipe 260 can both be installed on the inner wall of the box 100 to enhance the installation stability of the first communicating pipe 250 and the second communicating pipe 260.

Further, the data center of the container can also include a liquid inlet pump (not shown in the figures) and a liquid outlet pump (not shown in the figures). One end of the first communicating pipe 250 is located in the accommodating cavity 101 and communicates with a plurality of liquid inlet pipes 220, and the other end is located outside the accommodating cavity 101 and communicates with the liquid inlet pump, where the liquid inlet pump can transfer the cooling liquid into the cooling cavity 211, that is, to the cooling member 240 through the first communicating pipe 250 and the liquid inlet pipe 220 for refilling the consumed cooling liquid. One end of the second communicating pipe 260 is located in the accommodating cavity 101 and communicates with a plurality of liquid outlet pipes 230, and the other end is located outside the accommodating cavity 101 and communicates with the liquid outlet pump, where the liquid outlet pump can discharge the waste liquid from the cooling cavity 211, that is, from the cooling member 240, through the second communicating pipe 260 and the liquid outlet pipes 230, so as to provide space for the cooling liquid.

As an alternative embodiment, referring to FIG. 1 and FIG. 6, the container 10 may further include a mounting plate 500 for connecting the heat dissipation apparatus 200 to the top wall surface of the box 100. The installation manner of the mounting plate 500 can be a threaded connection realized with bolts, screws and other threaded parts, or a connection realized by welding. The installation manner of the heat dissipation apparatuses 200 is not limited by the present embodiment, nor is it limited to the above examples.

In the description of the embodiments of the present application, it should be understood that unless otherwise specified and limited, the terms “installation”, “connected with” and “connection” should be broadly understood, for example, they can be fixed connection, indirect connection through an intermediary, structural communication between two elements or interactive relationship between two elements. For those skilled in the art, the specific meanings of the above terms in this application can be understood according to the specific circumstances.

The orientations or positional relationships indicated by the terms “upper”, “lower”, “front”, “rear”, “vertical”, “horizontal”, “top”, “bottom”, “inner” and “outer” are orientations or positional relationships based on the accompanying drawings, which is only for the convenience of describing the present application and simplifying the description, and does not indicate or imply that the devices or elements referred to must have a specific orientation, be constructed and operated in a specific orientation, and therefore should not be construed as a limitation of this application. In the description of this application, “a plurality of” means two or more, unless it is precisely specified otherwise.

The terms “first”, “second”, “third” and “fourth” in the specification and claims of this application and the above drawings are used to distinguish similar objects, and are not necessarily used to describe a specific order or sequence. It should be understood that such data are interchangeable under appropriate circumstances, so that the embodiments of the present application described herein can be implemented in other orders than those illustrated or described herein. Furthermore, the terms “including” and “having” and any variations thereof are intended to cover non-exclusive inclusion, for example, a process, method, system, product or device that includes a series of steps or units is not necessarily limited to those explicitly listed, but may include other steps or units not explicitly listed or inherent to such process, method, product or device.

Finally, it should be explained that the above embodiments are only used to illustrate the technical scheme of the present application, but not to limit it. Although the present application has been described in detail with reference to the foregoing embodiments, it should be understood by those skilled in the art that the technical scheme described in the foregoing embodiments can still be modified, or the technical features of structural parts or full structures can be replaced by equivalents. However, these modifications or substitutions do not make the essence of the corresponding technical solutions deviate from the scope of the technical solutions of various embodiments of this application.

1. A container, comprising a box and a heat dissipation apparatus, wherein the box is provided with an accommodating cavity for placing an electronic device; the heat dissipation apparatus is located in the accommodating cavity and installed on an inner wall surface of the box;
the heat dissipation apparatus comprises a housing with a cooling cavity, wherein the cooling cavity is filled with a cooling liquid; the housing is provided with an inlet and an outlet which communicate the cooling cavity and the accommodating cavity; high-temperature gas in the accommodating cavity enters the cooling cavity through the inlet; and low-temperature gas in the cooling cavity generated after heat exchange with the cooling liquid enters the accommodating cavity through the outlet.

2. The container according to claim 1, further comprising a fan configured to transport the high-temperature gas in the accommodating cavity into the cooling cavity; and
the fan is installed in the cooling cavity, and an air inlet of the fan faces the inlet; or the fan is installed in the accommodating cavity, and an air outlet of the fan faces the inlet.

3. The container according to claim 2, wherein the heat dissipation apparatus further comprises a protective mesh, which is connected to the housing and covers the inlet; or, the protective mesh covers the fan.

4. The container according to claim 1, wherein the heat dissipation apparatus further comprises a liquid inlet pipe, a liquid outlet pipe and a cooling member, wherein the cooling member is located in the cooling cavity and between the inlet and the outlet; an axial direction of the inlet intersects with an axial direction of the outlet; a cavity of the cooling member is filled with the cooling liquid, and both the liquid inlet pipe and the liquid outlet pipe are communicated with the cavity of the cooling member, wherein the liquid inlet pipe is configured to introduce the cooling liquid into the cavity of the cooling member, and the liquid outlet pipe is configured to discharge a waste liquid in the cavity of the cooling member generated by the cooling liquid after a cooling process.

5. The container according to claim 4, wherein a number of the inlet is plural, and the plurality of inlets are arranged at intervals along a first direction; and
the number of the outlet is plural, and along a second direction, a part of the outlets are located at one side of the inlets, and another part of the outlets are located at the other side of the inlets, and the second direction intersects with the first direction.

6. The container according to claim 5, wherein the number of the cooling member is two, and the two cooling members are respectively arranged close to the outlets on both sides of the inlets.

7. The container according to claim 1, wherein the number of the heat dissipation apparatus is plural, and the plurality of heat dissipation apparatuses are arranged on a top wall surface or a side wall surface of the box at intervals; or, a part of the heat dissipation apparatuses are installed on the top wall surface of the box at intervals, and another part of the heat dissipation apparatuses are installed on the side wall surface of the box at intervals, wherein the top wall surface and the side wall surface are adjacent.

8. The container according to claim 7, wherein the container further comprises a first communicating pipe and a second communicating pipe, and
the first communicating pipe is communicated with a liquid inlet pipe of the plurality of heat dissipation apparatuses for transporting the cooling liquid; or, the second communicating pipe is communicated with a liquid outlet pipe of the plurality of heat dissipation apparatuses for transporting a waste liquid.

9. A data center of a container, comprising an electronic device and the container, the container comprises a box and a heat dissipation apparatus, wherein the box is provided with an accommodating cavity for placing the electronic device; the heat dissipation apparatus is located in the accommodating cavity and installed on an inner wall surface of the box;
the heat dissipation apparatus comprises a housing with a cooling cavity, wherein the cooling cavity is filled with a cooling liquid; the housing is provided with an inlet and an outlet which communicate the cooling cavity and the accommodating cavity; high-temperature gas in the accommodating cavity enters the cooling cavity through the inlet; and low-temperature gas in the cooling cavity generated after heat exchange with the cooling liquid enters the accommodating cavity through the outlet;
wherein the electronic device is located in the box of the container.

10. The data center of the container according to claim 9, wherein the container further comprises a fan configured to transport the high-temperature gas in the accommodating cavity into the cooling cavity; and
the fan is installed in the cooling cavity, and an air inlet of the fan faces the inlet; or the fan is installed in the accommodating cavity, and an air outlet of the fan faces the inlet.

11. The data center of the container according to claim 10, wherein the heat dissipation apparatus further comprises a protective mesh, which is connected to the housing and covers the inlet; or, the protective mesh covers the fan.

12. The data center of the container according to claim 9, wherein the heat dissipation apparatus further comprises a liquid inlet pipe, a liquid outlet pipe and a cooling member, wherein the cooling member is located in the cooling cavity and between the inlet and the outlet; an axial direction of the inlet intersects with an axial direction of the outlet; a cavity of the cooling member is filled with the cooling liquid, and both the liquid inlet pipe and the liquid outlet pipe are communicated with the cavity of the cooling member, wherein the liquid inlet pipe is configured to introduce the cooling liquid into the cavity of the cooling member, and the liquid outlet pipe is configured to discharge a waste liquid in the cavity of the cooling member generated by the cooling liquid after a cooling process.

13. The data center of the container according to claim 12, wherein a number of the inlet is plural, and the plurality of inlets are arranged at intervals along a first direction; and
the number of the outlet is plural, and along a second direction, a part of the outlets are located at one side of the inlets, and another part of the outlets are located at the other side of the inlets, and the second direction intersects with the first direction.

14. The data center of the container according to claim 13, wherein the number of the cooling member is two, and the two cooling members are respectively arranged close to the outlets on both sides of the inlets.

15. The data center of the container according to claim 9, wherein the number of the heat dissipation apparatus is plural, and the plurality of heat dissipation apparatuses are arranged on a top wall surface or a side wall surface of the box at intervals; or, a part of the heat dissipation apparatuses are installed on the top wall surface of the box at intervals, and another part of the heat dissipation apparatuses are installed on the side wall surface of the box at intervals, wherein the top wall surface and the side wall surface are adjacent.

16. The data center of the container according to claim 15, wherein the container further comprises a first communicating pipe and a second communicating pipe, and
the first communicating pipe is communicated with a liquid inlet pipe of the plurality of heat dissipation apparatuses for transporting the cooling liquid; or, the second communicating pipe is communicated with a liquid outlet pipe of the plurality of heat dissipation apparatuses for transporting a waste liquid.

17. The data center of the container according to claim 9, wherein along a height direction of the container, an orthographic projection of the electronic device on a bottom wall of the container is arranged at intervals from an orthographic projection of the heat dissipation apparatus of the container on the bottom wall of the container; and
along a height direction perpendicular to the box, an orthographic projection of the electronic device on a side wall of the container is arranged at intervals from an orthographic projection of the heat dissipation apparatus of the container on the side wall of the container.

18. The data center of the container according to claim 9, wherein along a height direction of the container, an orthographic projection of the electronic device on a bottom wall of the container is arranged at intervals from an orthographic projection of the heat dissipation apparatus of the container on the bottom wall of the container; or
along a height direction perpendicular to the box, an orthographic projection of the electronic device on a side wall of the container is arranged at intervals from an orthographic projection of the heat dissipation apparatus of the container on the side wall of the container.
